(19) United States
(12) Patent Application Publication
(10) Pub. No.: US 2004/0052942 A1
(43) Pub. Date: Mar. 18, 2004

(54) Method for coating substrates and mask holder

(76) Inventors: Frederik Bijkerk, Amsterdam (NL); Andrey E Yakshin, Nieuwegein (NL); Eric Louis, Ijsselstein (NL); Marcus Jozef Henricus Kessels, Nieuwegein (NL); Edward Lambertus Gerardus Maas, Eindhoven (NL); Caspar Bruineman, Almere (NL)

Correspondence Address: Hudak & Shunk Company, Suite 307, 2020 Front Street, Cuyahoga Falls, OH, 44221, US

(21) Appl. No.: 10/450,732

(22) PCT Filed: Dec. 14, 2001
(86) PCT No.: PCT/EP01/14728

(30) Foreign Application Priority Data
Dec. 15, 2000 (DE) 10062713.7

(51) Int. Cl. C23C 16/00; B05D 1/32

(52) U.S. Cl. 427/248.1; 427/282; 118/720; 118/500

(57) ABSTRACT

When coating substrates it is frequently desired that the layer thickness should be a certain function of the position on the substrate to be coated. To control the layer thickness a mask is conventionally arranged between the coating particle source and the substrate. This leads to undesirable shadow effects. In addition, is has so far only been possible to obtain rotationally symmetrical thickness distributions. It is now proposed that masks should be used having apertures aligned according to a regular grid on the mask surface. Such a mask with a mask holder comprising a base frame (2), an intermediate frame (3) and a mask frame (4) which are joined one to the other by means of double hinges (5a, a′, b, b′), is moved arbitrarily in the mask plane. By this means arbitrary thickness distributions can be achieved when coating substrates at reasonable cost.

### DESCRIPTION

The invention relates to a method for coating substrates by means of physical vapour deposition (PVD) and/or chemical vapour deposition (CVD) having any coating thickness distributions, especially for manufacturing optical single-layer or multi-layer systems for the visible, extreme ultraviolet and x-ray wavelength ranges, in which between at least one substrate to be coated and at least one particle source at least one mask is provided. In addition, the invention relates to a mask holder.

When coating substrates with a single layer or several layers it is frequently required that the layer thickness should be a certain function of the position on the substrate to be coated. This also includes the special thickness distribution of a constant thickness over the entire substrate surface. Such thickness distributions are important, for example, for manufacturing optical multi-layer systems for the visible, the extreme ultraviolet or the x-ray wavelength range having layer thicknesses constant over the substrate plane or continually extendable.

Single-layer and multi-layer systems are usually manufactured by PVD. Corresponding coating chambers contain one or several particle sources and at least one substrate to be coated. The particle sources can be ion sources or magnetrons. The particles can, however, also be obtained by electron beam evaporation or ion beam sputtering. In PVD coating the thickness distribution in the substrate plane depends on the relative position of the particle source relative to the substrate and on the angular distribution of the particles in the particle flow emanating from the particle source. Chemical vapour deposition methods differ from PVD methods in that the layer-forming material is produced by chemical reaction during the coating process.

Conventional approaches to compensate for the inhomogeneity in the spatial distribution of the particles in the particle flow and also the thickness distribution over the substrate plane involved moving the substrate relative to the particle source, i.e., about an axis of rotation running through the particle source. This was able to be optimised further by using planetary gearing in which the substrates were also rotated about their own axis of symmetry.

Another approach involved arranging a mask between the particle source and the substrate. This mask could, for example, take the form of a cake segment or a leaf.

Masks punched out in a quasi-flower shape were also used to achieve rotationally symmetrical thickness distributions (see, for example, DE 38 16 578 C1). One problem with using masks are shadow effects. In order to compensate for this, the masks were rotated relative to the substrate. In some cases, this rotation was also combined with the rotational movement of planetary gearing. The overall result was very complicated devices to achieve up to three different rotations simultaneously. It was only possible to apply rotationally symmetrical thickness distributions. In addition, the complex mechanisms of this apparatus were susceptible to heat. The vibrations emitted by the rotational drives led to defects in the coatings.

A method for manufacturing dipole antennae by sputtering is described in U.S. Pat. No. 4,303,489. The desired thickness distributions are achieved by accomplishing relative motion in all three spatial directions between the mask and/or the substrate and/or the source. This motion can involve translational, rotational or any other motion. In addition, the mask has an arbitrarily shaped aperture. In an optimised, preferred embodiment for the manufacture of antennae the substrates are rods which are rotated about their own axis. The mask has an equal-area aperture for each antenna substrate which are arranged along a one-dimensional grid. The masks and the substrates can be moved synchronously relative to the cathode.

In U.S. Pat. No. 6,010,600 an attempt was made to dispense with masks completely. In this PVD coating method the desired thickness distribution is achieved by skilfully moving the substrate relative to the source in the substrate plane coupled with rotating the substrate about its own axis. Preferred here is a constant substrate speed since this eliminates the influences of the substrate geometry on the thickness distribution. Unfortunately this approach can really only be realised for rotationally symmetrical thickness distributions. For an arbitrary thickness distribution the mathematical expenditure involved in calculating the equation of motion is too high or the equation of motion cannot be solved at all.

U.S. Pat. No. 5,993,904 discloses a method for coating substrates with one or several layers in vacuum using a mask. In the method proposed here the spatial particle intensity is only controlled via the mask to obtain the desired thickness distribution. These masks are three-dimensional with tunnels of different lengths. The tunnel length corresponds to an accepted solid angle from which particles can pass through the tunnel. The longer the tunnel, the smaller is this solid angle. In order to compensate for variations in the particle beam density, substrate and mask can also be rotated jointly about the particle source. In a preferred embodiment the mask has a honeycomb structure, i.e., the tunnel has hexagonal cross-sections. As a result, the shadow effect of the mask is reduced. However, the shadow effect cannot be avoided completely. Non-rotationally symmetrical thickness distributions can also be obtained using the afore-mentioned method. However, only relatively coarse thickness distributions can be achieved. This is because too small tunnel cross-sections would reduce the solid angles or the number of “allowed particles” too much for coatings to be accomplished in acceptable times. Another problem is the manufacture of such fine and differentiated honeycomb masks.

U.S. Pat. No. 5,948,468 discloses a method for correcting surface defects. For this purpose the shape and configuration of the apertures in a coating mask are calculated from the measured thickness deviations on the basis of Fourier transformations.

This patent uses also a mask, which consists of very small holes (100 μm or less). This is required because each point on the surface will receive deposition through at least about 75 different apertures. A practical disadvantage of this method is that these holes will get clogged as the deposition goes on. This results in a changing of the lateral transmission of the mask: smaller holes will suffer more then larger holes, and this changes the partial transmission.

WO 95/3436 describes a mask for reactive sputter coating. A predefined layer thickness distribution is achieved by varying the aperture size and mask thickness but this mask is not moving at all. This will result in a shadow of the mask thus a non-uniform deposition will occur. On view of the used deposition technique (sputter deposition) the large source will probably reduce this non-uniform to a level that is not enough for most purposes.

Mask holders are described in U.S. Pat. No. 4,615,781 and DD 1567 15. According to U.S. Pat. No. 4,615,781 the mask holder has means of avoiding stresses in the mask. In DD 1567 15 the ceramic foil to be coated is arranged between two masks in a comb-like mask holder, wherein the foil and the masks are held together by clamps.

Against this background the object of the present invention is to provide a method with the aid of which arbitrary thickness distributions can be achieved at reasonable cost. In this framework the object of the present invention is also to provide a mask holder.

This object is achieved by a method according to claim 1 and a mask holder according to claim 17.

In accordance with the method according to the invention, special masks having two or more apertures are used. Depending on the application one or several masks can be used. Especially if several evaporation sources are provided, each source can have a particular mask assigned to it.

The mask apertures are aligned on the mask surface according to a grid which can be described by the family of vectors pᵢ=nᵢ₁v₁+nᵢ₂v₂. The area of the apertures is for its part a function of the position of the aperture on the mask surface. Both the aperture position or the basis vectors v₁ and v₂ and the aperture area are selected as a function of the desired coating thickness distribution. A relative motion is accomplished between mask and/or substrate and/or particle source. The relative motion is tuned in such a way that the shadowing effect of the aperture pattern is reduced. The parameters of the relative motion, like speed and distance, are adapted to the strength of the shadowing effect in order to reduce this effect to approximately zero. The relative motion generally serves only to avoid any shadow effects which appear as a result of the mask. Shadow effects can be completely suppressed by suitably optimising the size of the sources and the geometrical spacings between the elements, source, mask and substrate.

In order to optimize the aperture pattern the following steps are preferred:

a) a mask having uniform aperture sizes is used and the substrate is coated, whereby a relative motion in two directions is performed,

b) the thickness distribution of the coating is measured and

c) the apertures are modified to increase or decrease the transmission of the mask locally in order to achieve the desired thickness distribution without shadows.

In step c the area A of the apertures can be modified according to the following general formula A≈A₀(s²−NU)(hₘ/hₛ)² where NU is the non-uniformity of the thickness of the coating, s equals the distance from the center of the substrate in mm, hₘ equals the distance from the mask to the source and hₛ equals the distance from the substrate to the source and A₀ is the area of the center aperture.

This is a typical example and only valid if the center of the source and of the substrate are aligned.

The masks can have arbitrary aperture sizes. Preferred is the range of 0.01 to 10 mm, especially 2 to 8 mm and 4 to 6 mm respectively. The distances between the centres of the apertures is in the preferred range of 0.02 to 11 mm, especially 2 to 9 mm and 4 to 6 mm respectively. In order to get a flat, uniform thickness distribution it is preferred to use a mask the apertures of which have different sizes. For most evaporation sources it is preferred to increase the aperture size from the aperture in the centre of the mask in a radial direction to the edge of the mask.

The relative motion can be any relative movements. It can be made up of a superposition of movements of the mask and/or the substrate and/or the particle source. Motion is possible in two or all three spatial directions. It can involve motion in one direction and motion in the forward and backward direction.

Other boundary conditions which must be taken into account when selecting the mask and the relative motion are the geometrical dimensions of the coating chamber and also the possible spacings and angles between the at least one substrate, the at least one particle source and the mask and also the expansion of the particle source.

With the aid of the present invention single-layer or multi-layer systems can be manufactured with a completely arbitrary coating thickness distribution. The symmetry of the substrate, e.g. whether it is plane or curved, is also arbitrary. In particular, non-rotationally symmetrical thickness distributions can also be produced. Thus, the method according to the invention can also be used to apply coatings merely to controlled areas, for example in order to correct already existing coatings.

It has proved advantageous to also take into account the spatial distribution of the particles in the particle flow and the desired coating thickness distribution when selecting the areas of the apertures.

Particular classes of relative motion have also proved to be particularly advantageous. Thus, the relative motion can be accomplished discontinuously in stages or as a sequence of steps. It can be accomplished at a constant speed. It can have a rotational component, especially about the axis of symmetry of the substrate and/or the mask and/or the particle source. It can also correspond to a periodic function. In this case, it has proved advantageous to select the amplitude of the relative motion as a function of the position and the area of the mask apertures or to select it as a function of the length of the vector v₁ or v₂. Quite especially preferred in this context are relative motions which can be described by sine functions or periodically repeating triangular functions or a saw-tooth function. It has proved especially successful to superpose representatives of the classes of relative motion described above to form an overall relative motion.

The mask holder according to the invention has a base frame, an intermediate frame, a mask frame and at least two double hinges. Here double hinges are taken as components which have hinge-like joints with the neighbouring component at two opposite ends. The hinges connect the frames such that the base frame is connected to the intermediate frame and the intermediate frame is connected to the mask frame which holds the mask. This should ensure that, on the one hand, the mask frame can move translationally relative to the intermediate frame and the base frame and, on the other hand, the intermediate frame can move translationally in another direction relative to the base frame, wherein the mask frame is moved synchronously.

In order to accomplish the motion, motors can be connected to the intermediate frame and/or the mask frame, for example, which can drive different velocity ramps. By superposing the motion in one direction and the motion in the other direction, an arbitrary number of relative motions can be combined. The number of possibilities is raised to a higher power if the spacing between the complete mask holder and the substrate or the particle source is also varied.

Preferably the double hinges are applied to the frames so that the motion of the intermediate frame relative to the base frame is perpendicular to that of the mask frame relative to the intermediate frame.

For reasons of stability the mask holder preferably has a total of four double hinges of which respectively two are arranged on the opposite side of the mask holder.

The invention is now explained in detail with reference to the drawings where

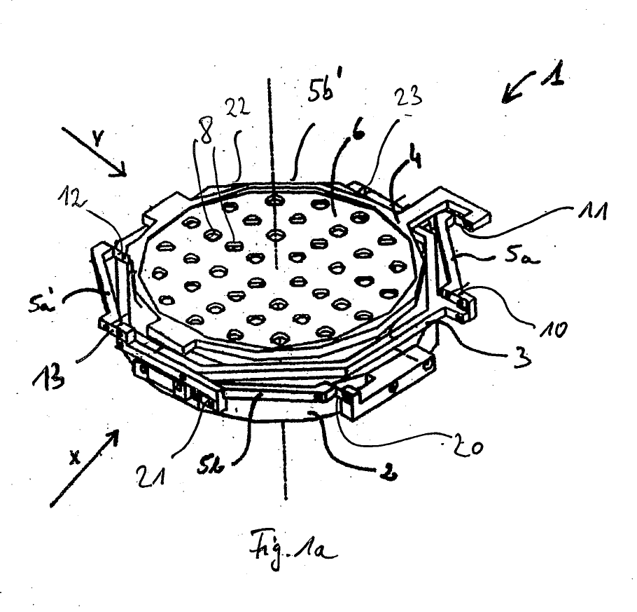

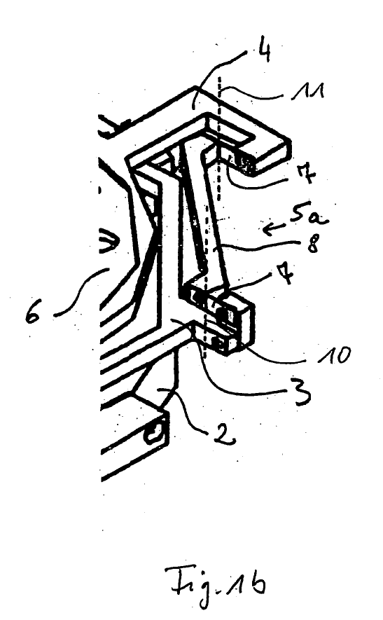

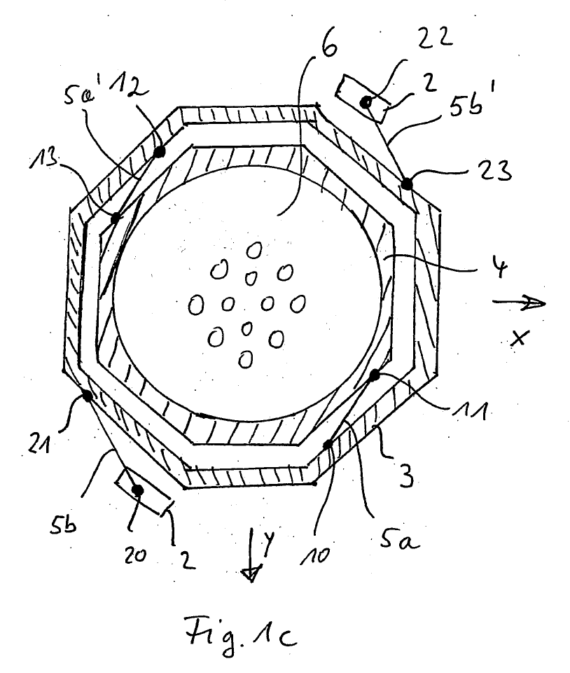

FIGS. 1a, b is a perspective view of the mask holder and a double hinge according to the invention;

FIG. 1c a schematic top view of the mask holder according to FIG. 1a;

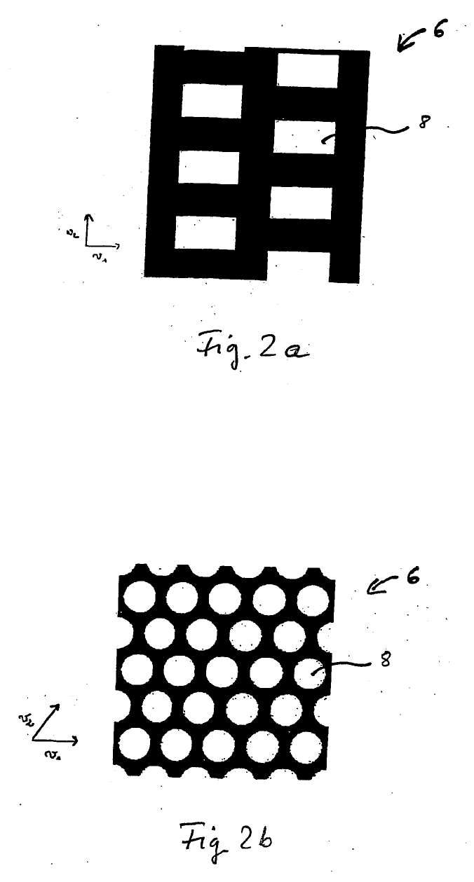

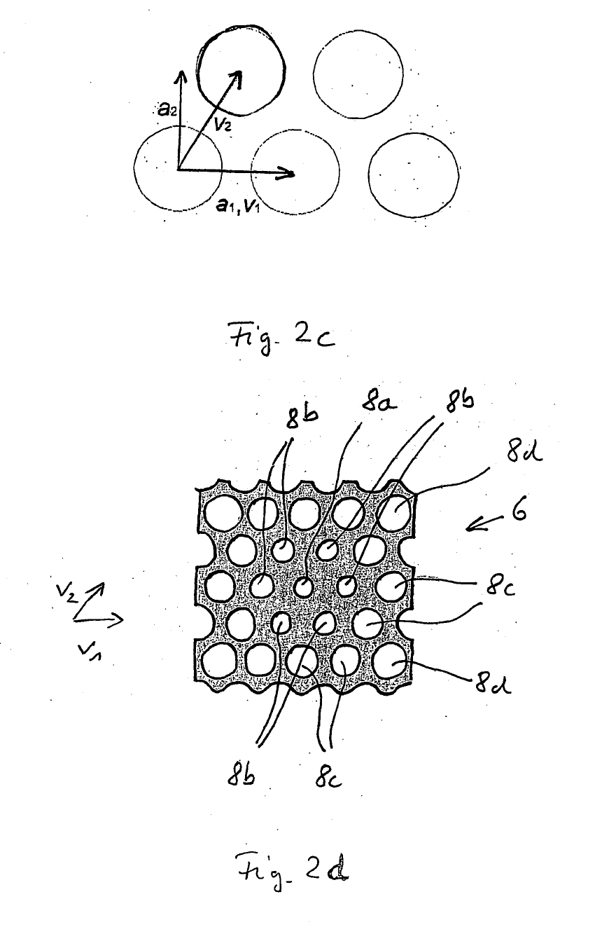

FIGS. 2a, d are examples of masks to be used in the method according to the invention;

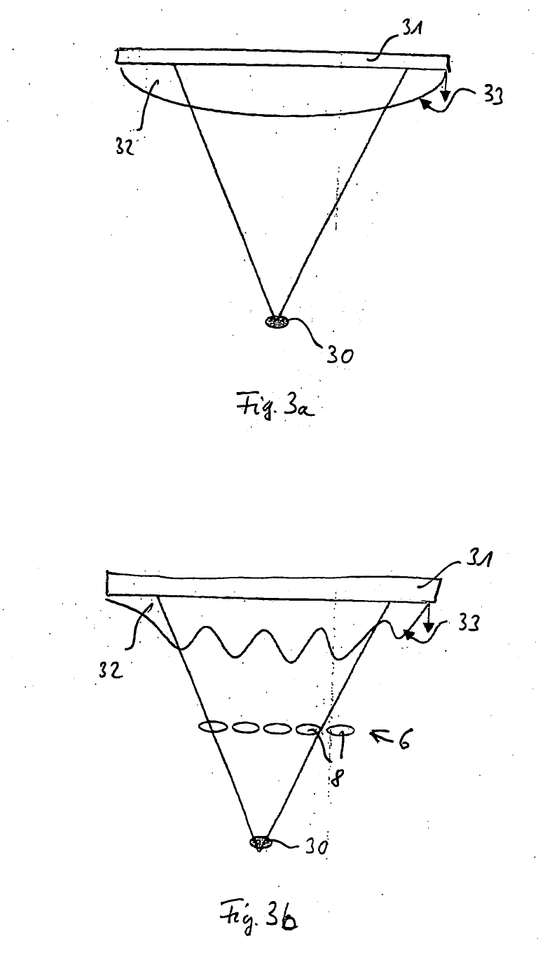

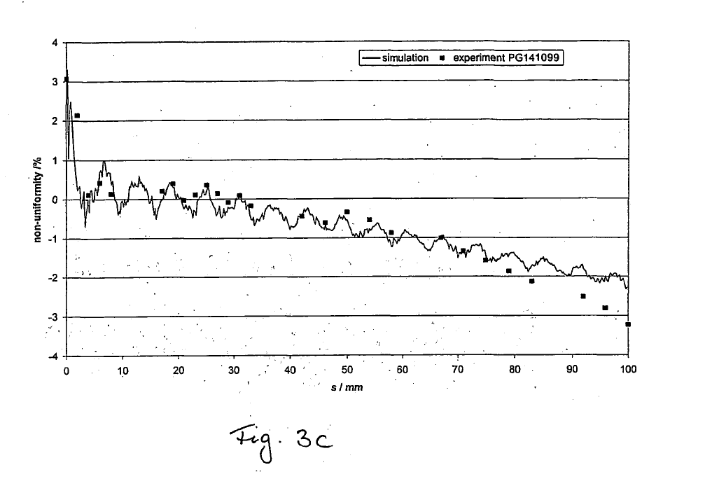

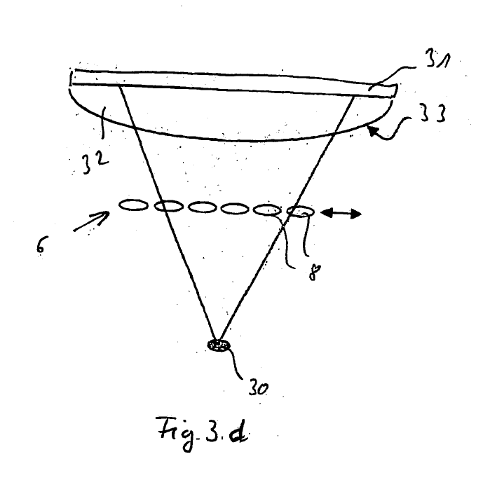

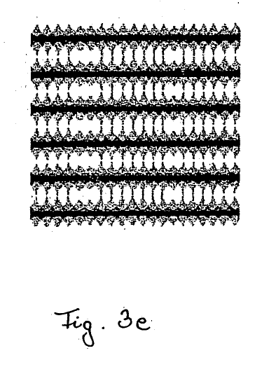

FIG. 3a a schematic representation of a standard arrangement;

FIG. 3b a schematic representation with a stationary mask;

FIG. 3c a diagramm showing the non-uniformity of coating thickness in dependance from the distances from the centre of the substrate;

FIG. 3d a schematic arrangement with a moving mask;

FIG. 3e a coating pattern achieved with an arrangement according to FIG. 3d where the mask is very close to substrate (only for demonstration);

FIG. 3f a schematic arrangement with a moving mask according a another embodiment;

FIG. 3g a schematic arrangement according to another embodiment;

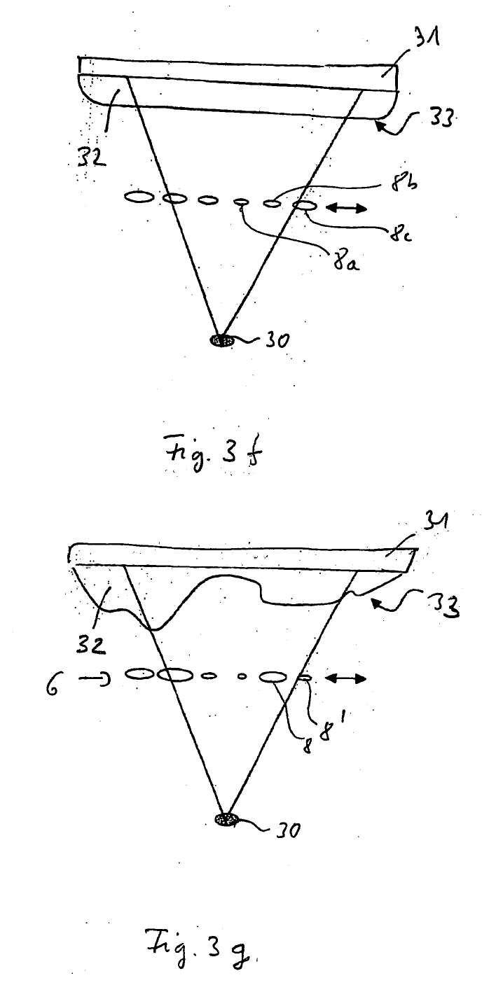

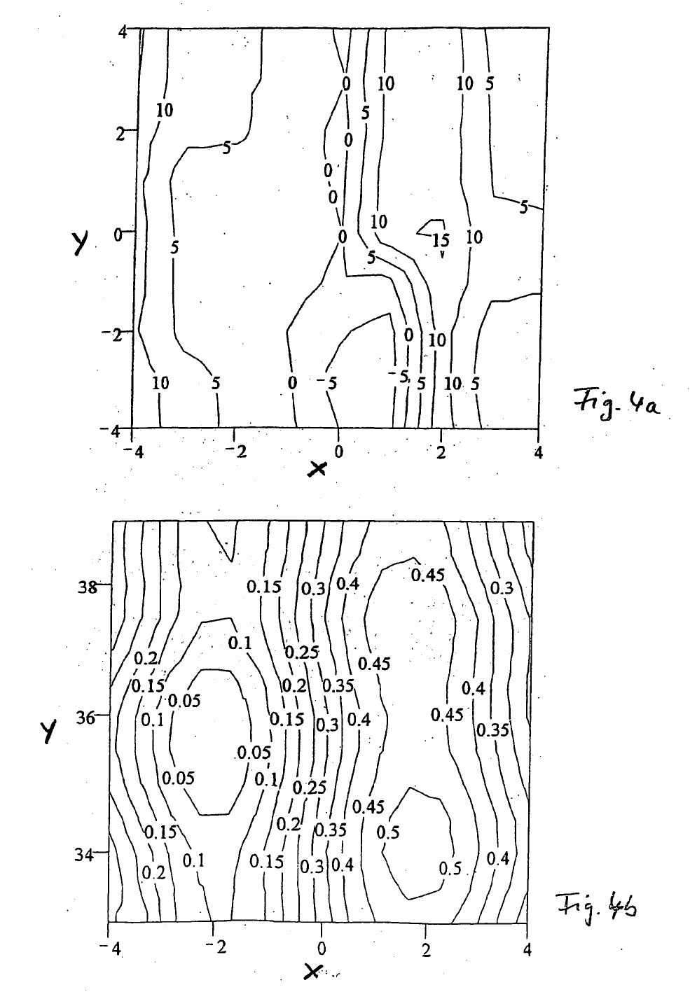

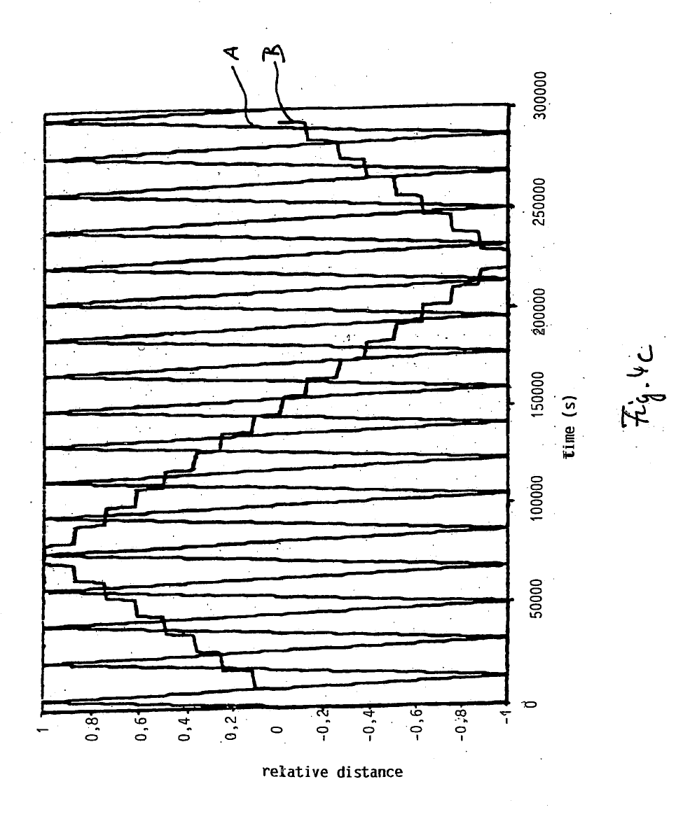

FIG. 4a shows the relative deviations of a thickness distribution obtained using the stationary mask as in FIG. 2a, from the desired thickness distribution;

FIG. 4b shows the relative deviations of a thickness distribution obtained using the moving mask as in FIG. 2a, from the desired thickness distribution and

FIG. 4c is a diagram showing the movement accomplished to produce the thickness distribution as in FIG. 4b.

FIG. 1a shows a mask holder 1. The main components are the base frame 2, the intermediate frame 3 and the mask frame 4 which holds the mask 6. The base frame 2 is connected via the double hinge 5b and the almost completely concealed double hinge 5b′ to the intermediate frame 3. This intermediate frame 3 is connected via the double hinge 5a and the double hinge 5a′ to the mask frame 4. The double hinges 5a and 5a′ and the double hinges 5b and 5b′ are arranged respectively on the opposite sides of the mask holder 1. As a result of the mask frame 4 being suspended in the base frame 2 via the intermediate frame 3 and the double hinges 5a, 5a′, 5b, 5b′ having swivel axes 10-13, 20-23, the mask frame 4 can move in the x-y plane. The double hinges 5a and 5a′ essentially allow movement in the x-direction and the double hinges 5b and 5b′ essentially allow movement in the y-direction. The directions of translation are shown by the arrows in FIG. 1 and are perpendicular one to another. Rotational movement cannot be accomplished.

To enable a better understanding the double hinge 5a from FIG. 1a is shown enlarged in FIG. 1b. The double hinge 5a, like the other double hinges' 5a′, 5b and 5b′, essentially consists of two hinges 7 via which the double hinge 5a is linked to the intermediate frame 3 or the mask frame 4, and a rigid connection 8 between the two hinges 7. The swivel axes 10, 11 of the hinges 7 are shown by the dashed lines and are perpendicular to the mask plane.

FIG. 1c shows a schematic top view of the mask holder. The individual double hinges 5a, 5b, 5a′ and 5b′ respectively have swivel axes represented by pivot points 20, 21, 12, 13, 22, 23 and 10, 11. The intermediate frame 3 is also only shown schematically wherein the pivot points 20 and 22 as well as 11 and 13 lie respectively below or above the intermediate frame 3. The pivot points 11, 13, 20 and 22 are only shown outside the pivot frame to give a better understanding. It can easily be seen that the double hinges 5b, 5b′ and 5a and 5a′ required respectively for a direction of motion are arranged opposite to each other. The hole pattern of the mask and the arrangement concerning the movement mechanism depends on the coating method and desired thickness distribution, but are not limited to the coating method.

Motors which can drive arbitrary velocity ramps can be attached to the intermediate frame 3 and the mask frame 4. In addition, the entire mask holder 1 can be secured in an apparatus which varies the height of the mask holder and thus the mask in the coating chamber or moves the mask holder about an axis of rotation indicated by the dashed line or any arbitrary other axis of rotation. In the coating chamber the mask holder 1 is arranged so that the particle source is located on the side of the base frame 2 and the substrate to be coated is located on the side of the mask frame 4 or conversely.

As an example, FIGS. 2a, 2b and 2d show three masks 6 such as could be used in a method according to the invention to avoid shadow effects during vapour deposition.

The mask 6 in FIG. 2a has rectangular apertures 8 which all have the same area. The grid according to which these apertures 8 are arranged on the mask 6 can be described by the basis vectors to the left of the mask v₁ and v₂ and likewise corresponds to a family of vectors pᵢ=nᵢ₁v₁+nᵢ₂v₂.

The apertures 8 of the mask 6 from FIG. 2b all have the same circular shape and the same area. The grid according to which the apertures 8 are arranged on the mask 6 can be described by the basis vectors v₁ and v₂ shown on the left of the mask 6 and in greater detail in FIG. 2c. Typical values for the masks are diameter of the holes 0.01-10 mm preferably 3 mm. The distances between the centres of the apertures is in the range of 0.02-11 mm preferably 4 mm.

Typical lenghts of the vectors v₁ and v₂ are 0.02-11 mm. Both are 4 mm in the preferred embodiment. The angle between the two vectors equals 60 degrees. The complete mask can be described with the formula p=n₁v₁+n₂v₂. The integer set (n₁,n₂) indicate a particular apertures on the mask. They function as a sort of coordinate-system. The apertures in the center will have the combination (0,0), the hole to the right will have (1,0), and the apertures above (0,1).

The mask 6 in FIG. 2d has circular apertures 8a-d. The aperture 8a located in the centre of the mask has the smallest diameter. The diameter of the apertures 8b, 8c and 8d increases in a radical direction starting form aperture 8a.

In connection with FIGS. 3a-3g the method is described in detail.

The source can be any source (PVD, CVD, point-like or area-like), preferably a source with a particle beam primarily directed towards a substrate. The angular distribution of the particle flux may be arbitrary, but constant during the deposition process. It is one of the major claims of this patent that the initial flux distribution of the source can be modified by the invention to another arbitrary, and especially non-rotationally symmetric distribution, for example a flat distribution, or a two-dimensional thickness profile without rotation symmetry.

A source with small dimensions enables the most detailed thickness profile on the substrate, i.e. many variations of the thickness across the surface. Larger source areas will reduce the number of details in the variation in the thickness profile, i.e. fewer variations of the thickness (or features) across the surface.

### EXAMPLE

An evaporation set-up based on e-beam evaporation may employ a source with a circular size of 3 mm. The particle source is disposed at the bottom of a ultra-high vacuum chamber. The distance from the source to the substrate to be coated amounts 1000 mm, with the mask positioned at 333 mm from the source. The smallest lateral variation across the surface of the thickness profile of the coated layer is in the range of 9 mm.

A schematic representation of a standard arrangement having no mask is shown in FIG. 3a. The usually non-uniform particle distribution of source 30 results in non-uniform thickness profile 33 of the coating 32 deposited on substrate 31.

When no mask is used, the coating 32 will be thicker in the centre as compared to the outer sides. The difference in layer thickness (peak-valley) is determined by the angular distribution of the source, and in most cases it is approximately 5%. Typical layer thickness are 3 to 4 nm and a mirror coated on the substrate consists 100 layers. To be able to make uniform coatings over the complete surface the particle distribution should be changed.

In FIG. 3b a mask 6 according to FIG. 2b having apertures 8 of the same size is located between source 30 and substrate 31. Due to the shadowing effect a wiggle is introduced on the thickness distribution.

In FIG. 3c the effect of the mask shadow on the non-uniformity is shown.

If mask 6 is moved the wiggle disappears as shown in FIG. 3d.

When one starts to move the mask back and forth over exactly the same distance (or a integer times this distance) as the distance between the centres of the holes the shadowing will reduce, as shown in FIG. 3e. The mask is moved by a step-by-step process and only 4 steps are shown. When one starts to move in the other direction as well, the shadowing will disappear completely.

The pattern of movement should be preferably triangular step-like in one direction and triangular in the other direction (both in the same, plane parallel to the substrate to be coated). Both movements should be synchronised as shown in FIG. 4c. The movement essentially eliminates a modulation or shadowing effect of the mask hole structure on the substrate. Both the movement precision and the hole pattern precision determine the degree of suppression of the shadowing effect. The movement needs to be constant within one direction and cannot be sinusoidal, non-synchronised or non-periodic. All items discussed so far are needed to remove the influence of the shadowing of the mask.

To create a particular coating thickness distribution and/or removing the non-uniform angular distribution of the particle flux, the size of the holes in the mask are enlarged or reduced in order to respectively increase or reduce the average mask transmission. A typical variations of the layer thickness over the surface might be in the range from 0 to a few 10% with a corresponding change in mask hole sizes.

The shadowing effect has now been removed from the deposition-process and one can start making modifications to the mask to increase or decrease the transmission locally. For example, of one requires a uniform coating, it's necessary to compensate for the angular distribution of the source. So the sizes of the holes has to be increased as one gets farther form the center. The area of the outermost holes should be increased for example with three percent. Since in our case the non-uniformity on the substrate obeys the formula: NU−3.89×10⁻⁴s² (where s equals the distance from the centre of the substrate in mm) the area A of the holes should be increased according to the following formula: A≈3×(1+3.89×>10⁻⁴)(s×hₘ/hₛ)². Where hₘ equals the distance from the mask to the source (for example 500 mm) and hₛ equals the distance from the substrate to the source (typical 1000 mm).

This measure is shown in FIG. 3f where the area of the apertures 8b, 8c at a larger distance from the center of mask 6 (it's aperture 8a) are increased to enhance the transmission. The distance between the centers of the apertures should remain constant and periodic.

In order to achieve an arbitrary thickness profile 33, sizes of aperture 8′8′ are changed accordingly as shown in FIG. 3g.

FIG. 4a shows a distribution of the percentage deviations in the substrate plane (x, z) of a thickness distribution, which was produced using a stationary mask as shown in FIG. 2a, from the desired thickness distribution. The relative spacing of the apertures 8 or the length of the vectors v₁ and v₂ was 4 mm in this case. The diameter of the apertures 8 was 3 mm. The coating produced in this fashion exhibits strong shadow effects which are observed in particular as very abrupt fluctuations in thickness. The deviations were between −5% and 15% from the desired coating thickness. The peak-valley value of the uniformity is 23%.

However, during the manufacture of the coating whose percentage deviations from the desired thickness distribution are shown in FIG. 3b, the mask was moved continuously. FIG. 4c shows the relative trend of the motion executed in the x direction (curve A) and in the y direction (curve B). This is a triangular function which describes linear forward and backward motion (curve A) or a triangular step function (curve B) whose periods correspond to 15 periods of curve A and step width corresponds to one period of curve A. The amplitudes were 8.15 mm in the x direction and 10.5 mm in the y direction. As a result of this motion the peak-valley value of the uniformity was improved to 0.53%. The percentage thickness deviations were only between 0.05% and 0.45%.

By suitably optimising the size of the source and the geometric spacings between the individual elements, mask, substrate and source, the peak valley value of the uniformity can in principle be improved to 0%. The mask itself can also be optimised with respect to surface shape and size and position of the apertures. The uniformity can also be improved to 0% by optimising the amplitudes in this case to 8.10 mm in the x direction and 10.38 mm in the y direction.

Given this, the thickness distribution shown in FIG. 4b is not yet the final desired distribution T(x, y) but an intermediate distribution N(x, y)where the shadow effects have first been eliminated. Ultimately desired is a distribution T(x, y) where the thickness of the coating may be increased at the substrate edges.

Then, the masks must be modified in accordance with a factor f(x, y)=T(x.1, y.1)/N(x.1, y.1) where 1 is the ratio of the mask-source distance to the substrate-source distance. This modification can take the form of a local enlargement/reduction in the aperture areas in the mask as shown in FIG. 2d or in a local change in the mask thickness.

1. A method for coating substrates by means of physical vapour deposition (PVD) and/or chemical vapour deposition (CVD) having any coating thickness distributions, especially for manufacturing optical single-layer or multi-layer systems for the visible, extreme ultraviolet and x-ray wavelength ranges, in which between at least one substrate to be coated and at least one particle source at least one mask is provided, characterised in that
a mask with i>1 apertures is used, whose position on the mask surface is described by the family of vectors pᵢ=nᵢ₁v₁+nᵢ₂v₂ and whose area is a function of the position, wherein the family of vectors depends on the desired thickness distribution, i is a natural number, nᵢ₁ and nᵢ₂ are integers and v₁, v₂ and pᵢ are vectors;
relative motion is accomplished between mask and/or substrate and/or particle source.

2. Method according to claim 1 characterized by the steps:
a) a mask having uniform aperture sizes is used and, the substrate is coated, whereby a relative motion in two directions is performed,
b) the thickness distribution of the coating is measured and.
c) the apertures are modified to increase or decrease the transmission of the mask locally in order to achieve the desired thickness distribution without shadows.

3. Method according to claim 2 characterized in that in step c the area A of the apertures is modified according to the following formula A≈A₀(s²−NU)(hₘ/hₛ)² where NU is the non-uniformity of the thickness of the coating, s equals the distance from the center of the substrate in mm, hₘ equals the distance from the mask to the source and hₛ equals the distance from the substrate to the source and A₀ is the area of the center aperture.

4. Method according to one of the claims 1 to 3 characterized in that a mask is used that has apertures with diameters in the range of 0.01 to 10 mm whereby the distances between the centres of the apertures is in the range of 0.02 to 11 mm.

5. Method according to one of claims 1 to 4 characterized in that a mask is used that has apertures sizes that increase as one gets farther from the center.

6. The method according to one of claims 1 to 5, characterised in that a mask is used where the area of the apertures is selected as a function of the spatial distribution of the particles in the particle flow and the desired coating thickness distribution.

7. The method according to one of claims 1 to 6, characterised in that the relative motion is accomplished such that it can be described by a step function.

8. The method according to one of claims 1 to 6, characterised in that the relative motion is accomplished at a constant speed.

9. The method according to one of claims 1 to 6, characterised in that the relative motion is accomplished such that it has a rotational component, especially about an axis of symmetry of the substrate and/or the mask and/or the particle source.

10. The method according to one of claims 1 to 6, characterised in that the relative motion is accomplished such that it can be described by a periodic function.

11. The method according to claim 10, characterised in that the amplitude of the relative motion is selected as a function of the position and area of the mask apertures.

12. The method according to claim 10, characterised in that the amplitude of the relative motion is a function of the length of the vector v₁ and/or V₂.

13. The method according to one of claims 10 to 12, characterised in that the relative motion is accomplished such that it can be described by a sine function.

14. The method according to one of claims 10 to 12, characterised in that the relative motion is accomplished such that it can be described by a periodically repeating triangular function.

15. The method according to one of claims 10 to 12, characterised in that the relative motion is accomplished such that it can be described by a saw-tooth function.

16. The method according to one of claims 7 to 15, characterised in that the relative motion is accomplished such that it can be described as the superposition of said motions.

17. A mask holder especially for use in methods according to claims 1 to 16 with a base frame (2), an intermediate frame (3) and a mask frame (4) and at least two double hinges (5a, 5a′, 5b, 5b′), wherein at least one (5b, 5b′) of the at least two double hinges (5a, 5a′, 5b, 5b′) joins the base frame (2) to the intermediate frame (3) and at least one (5a, 5a′) of the at least two double hinges (5a, 5a′, 5b, 5b′) joins the mask frame (4) to the intermediate frame (3).

18. The mask holder according to claim 17, characterised in that the double hinges (5a, 5a′, 5b, 5b′) are attached such that the movement of the intermediate frame (3) relative to the base frame (2) in the mask plane allowed by the double hinges (5a, 5a′, 5b, 5b′) is perpendicular to that of the mask frame (4) relative to the intermediate frame (3).

19. The mask holder according to claim 17 or 18, characterised in that it has a total of four double hinges (5a, 5a′, 5b, 5b′) of which respectively two are arranged on opposite sides of the mask holder (1).
